(19) United States
(12) Patent Application Publication
(10) Pub. No.: US 2008/0218968 A1
(43) Pub. Date: Sep. 11, 2008

(54) WINGED PIEZO FAN

(76) Inventors: Anandaroop Bhattacharya, Bangalore (IN); Rajiv K. Mongia, Fremont, CA (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/683,902

(22) Filed: Mar. 8, 2007

(51) Int. Cl. H05K 7/20; H02N 2/00

(52) U.S. Cl. 361/695; 310/328

(57) ABSTRACT

A winged piezo-fan to dissipate the heat generated by the devices in an electronic system is disclosed. The winged piezo-fan may comprise a piezo-ceramic element and two blades. The blades may be coupled to the piezo-ceramic element, which may change its physical dimension in response to receiving an alternating voltage signal. The blades coupled to the piezo-ceramic element may move upwards and downwards in a direction that is perpendicular to the axis drawn along the length dimension of the blades in response to the changes in the physical dimension of the piezo-ceramic element. The movement of the blades may cause a flapping movement, which may create turbulence in the surrounding air. The turbulence so created may create eddies, which may dissipate the heat generated by the devices positioned close to the winged piezo-fan.

### BACKGROUND

An electronic system may comprise a plurality of devices such as electronic components and integrated circuits, which may operate at a pre-specified power level. The devices may operate at low power and high power levels. For example, the memory, the voltage regulator, the wireless local area network (WLAN) devices may operate at low power levels and a microprocessor or a chipset may operate at a relatively higher power level. The devices may generate heat while performing their operation. The heat generated by the devices may be dissipated using cooling techniques such as providing air flow using dedicated fans, or pumped liquid cooling loops, or heat pipes. The heat dissipation may be performed to maintain the temperature levels within the pre-specified thermal limits to ensure reliable operation of the devices. The low power devices may also generate heat, which may need to be dissipated to enable the low power devices to operate optimally.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 illustrates a conventional piezo-fan 100.

FIG. 2 illustrates a winged piezo-fan 200.

FIG. 3 illustrates an embodiment of a winged piezo-fan 200 cooling a daughter card 300 comprising memory devices on both the planes.

### DETAILED DESCRIPTION

The following description describes a winged piezo fan. In the following description, numerous specific details such as logic implementations, or duplication implementations, types and interrelationships of components are set forth in order to provide a more thorough understanding of the present invention. It will be appreciated, however, by one skilled in the art that the invention may be practiced without such specific details. In other instances, structures have not been shown in detail in order not to obscure the invention. Those of ordinary skill in the art, with the included descriptions, will be able to implement appropriate functionality without undue experimentation.

References in the specification to “one embodiment”, “an embodiment”, “an example embodiment”, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

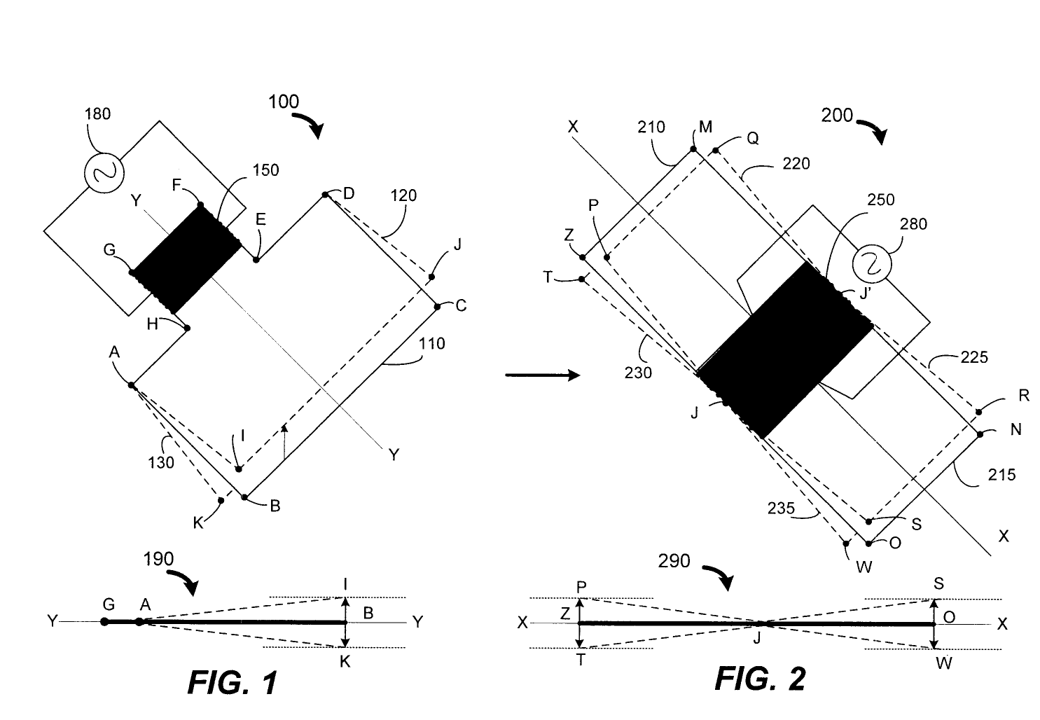

An embodiment of a conventional piezo-fan 100 is illustrated in FIG. 1. The piezo-fan 100 may comprise a blade 110, a piezo-ceramic element 150, and a voltage source 180. The blade 110 may comprise a sheet of metal or plastic marked by the surface 110 (ABCDEFGHA). The piezo-ceramic element 150 may be attached to the blade 110 along the edge FG as shown in FIG. 1. The piezo-ceramic element 150 may be coupled to a voltage source 180, which may provide alternating voltage signal at a frequency that may match the resonating frequency of the piezo-fan 100.

The piezo-ceramic element 150 may change its physical dimensions (compress or elongate) in response to receiving alternate cycles of the voltage signal. As a result, the blade 110 may move to a new position 120 (AIJDEFGHA) and 130 (AKLDEFGHA) while moving in the upward and the downward direction in a plane perpendicular to the Y-Y axis. The upward and downward movement of the blade 110 may create a flapping movement. The cross-sectional view 190 depicts that the flapping movement of the blade 110 with A as the pivotal point. However, the physical dimensions of the blade 110 also determine the weight of the blade 110, which may limit the size of the blade 110 to be increased beyond a limiting value. Also, the size of the piezo-fan 100 may be limited by the availability of space to house the piezo-fan 100.

An embodiment of a winged piezo-fan 200 is illustrated in FIG. 2. In one embodiment, the winged piezo-fan 200 may comprise two blades 210 (JZMJ′) and 215 (JONJ′), a piezo-ceramic element 250, and a voltage source 280.

In one embodiment, the two blades 210 and 215 may be made of metal or plastic and may be thin and narrow. In one embodiment, the piezo-ceramic element 250 may comprise materials such as lead zirconate titanate (Pb[ZrxTi₁₋ₓ]O₃0<x<1) (PZT), which exhibits piezo-electric effect. In one embodiment, the piezo-electric effect may refer to the property of the material to develop a voltage difference across two of its faces if the physical dimension of the material is changed, or physically changes shape with an applied external electric field. For example, the piezo-ceramic element 250 may compress during the positive half cycles of the voltage signal and expand during the negative half cycles of the voltage signal received from the voltage source 280.

In one embodiment, in response to receiving a positive half cycle of the voltage signal from the voltage source 280, the piezo-ceramic element 250 may compress. As a result of the compression of the piezo-ceramic element 250, the blades 210 and 215 attached to the piezo-ceramic element 250 may move upwards in a plane perpendicular to the X-X axis. In one embodiment, the blades 210 and 215 may be hinged at the center of the piezo-ceramic element 250.

In one embodiment, the blades 210 and 215 may move to a new position 220 (JPQJ′) and 225 (JSRJ′), which is at an angle to the axis X-X. In one embodiment, the axis X-X may be drawn parallel to the length dimension (JZ and JO) of the blades 210 and 215. Likewise, in response to receiving a negative half cycle of the voltage signal from the voltage source 280, the piezo-ceramic element 250 may elongate. As a result of such elongation of the piezo-ceramic element 250, the blades 210 and 215 attached to the piezo-ceramic element 250 may move downwards from the axis X-X hinged at the center of the piezo-ceramic element 250. In one embodiment, the blades 210 and 215 may move to a new position 230 (JTUJ′) and 235 (JWVJ′), which is at an angle to the axis X-X.

As a result of the upward and downward movement of the blades 210 and 215, a flapping movement may be created in a plane perpendicular to the X-X axis. By matching the frequency of the voltage signal and the resonating frequency of the piezo-ceramic element 250, the flapping movements may be maximized. Such flapping movements may cause turbulence in the air flow, which may create eddies or small circular movement of air. Eddies thus created may provide cooling effect to the electronic components or integrated circuits that may be placed close to the winged-piezo-fan 200.

A view 290 illustrates the cross section of the winged piezo-fan 200. The view 290 depicts that the flapping movement is on both sides of the pivotal plane (J-J′). The flapping movements may be created on both sides of the pivotal plane (J-J′) with a single piezo-ceramic element 250.

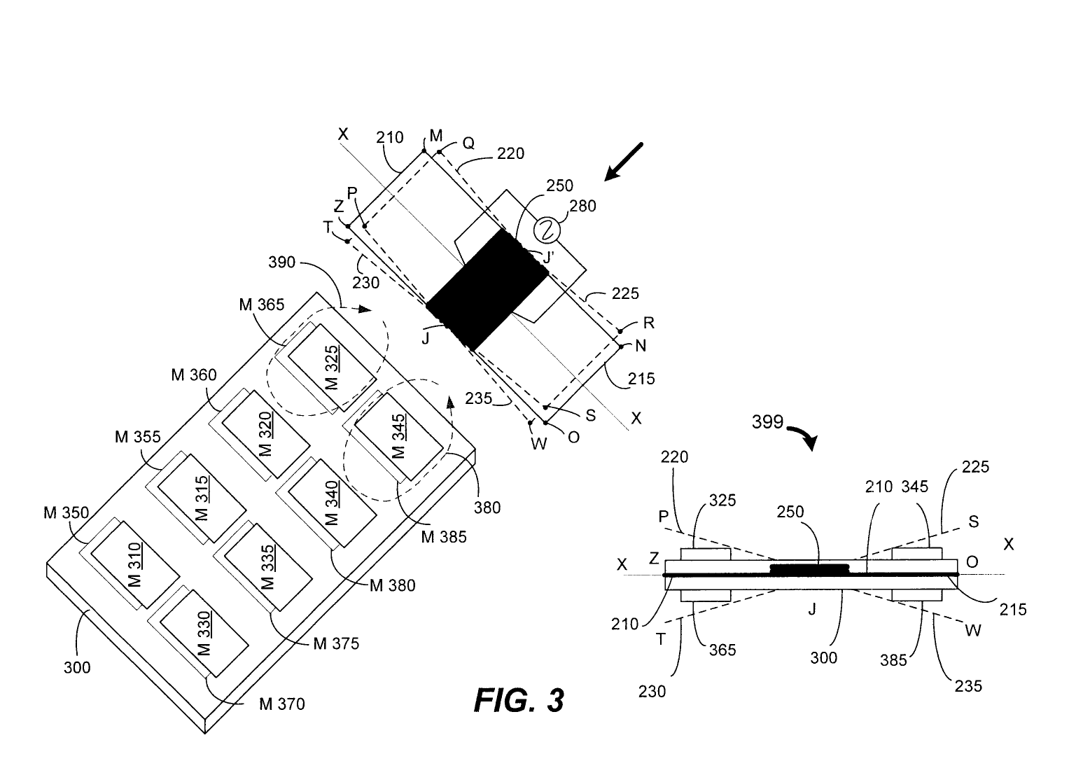

An embodiment of the winged piezo-fan 200 cooling a daughter card 300 is illustrated in FIG. 3. In one embodiment, the daughter card 300 may comprise memory chips M310 to M345 fixed to a first plane and memory chips M350 to M385 fixed to a second plane of the dual-plane memory card 300. In one embodiment, the memory chips may comprise dual in-line memory modules (DIMM), which operate at low-power levels. In one embodiment, the heat generated by the memory chips M310 to M345 and M350 to M385 may be dissipated using a winged piezo-fan 200. In one embodiment, the winged piezo-fan 200 may be positioned close to the daughter card 300 as depicted in FIG. 3.

In one embodiment, the blades 210 and 215 of the winged-piezo fan 200 may move upwards and downwards in a plane perpendicular to X-X axis causing a flapping movement in response to providing the voltage signal to the piezo-ceramic element 250. In one embodiment, the flapping movement of the blades 210 and 215 may cause turbulence in the air. The turbulence so caused may create eddies, which may in turn create small circular movements of air as depicted by 380 and 390.

In one embodiment, the turbulence may create a plurality of eddies, which may dissipate the heat generated by the memory chips M310 to M345 and M350 to M385. Such heat dissipation may provide a cooling effect to the memory chips M310 to M345 and M350 to M380. In one embodiment, the winged piezo-fan 200 comprising a single piezo-ceramic element 250 and the blades 210 and 215 may provide cooling effect to the memory chips M310 to 345 and M350 to M380 fixed, respectively, on both the planes of the daughter card 300.

A cross-sectional view 399 of the daughter card 300 and the winged piezo-fan 200 illustrates the flapping movement of the blades 210 and 215, which during alternate cycles of the voltage signal create eddies, respectively, on the first plane and the second plane of the daughter card 300.

The cross-sectional view 399 depicts that the flapping movement of the blade 210, while in the upward position JPQJ′, dissipates the heat generated by the memory chips M310 to 325. Likewise, the flapping movement of the blade 210, while in the downward position JTUJ′, dissipates the heat generated by the memory chips M350 to 365. Likewise, the flapping movement of the blade 215 dissipates the heat generated by the memory chips M330 to 345 while in the upward position JSRJ′ and the memory chips M370 to M385 while in the downward position JWVJ′.

Certain features of the invention have been described with reference to example embodiments. However, the description is not intended to be construed in a limiting sense. Various modifications of the example embodiments, as well as other embodiments of the invention, which are apparent to persons skilled in the art to which the invention pertains are deemed to lie within the spirit and scope of the invention.

What is claimed is:

1. A winged piezo-fan comprising:
a piezo-ceramic element that changes its physical dimension in response to receiving an alternating voltage signal, and
a first blade and a second blade is coupled to the piezo-ceramic element, wherein the first blade and the second blade moves in the upward and downward direction in a plane perpendicular to the axis along the length of the blades,
wherein the upward and the downward movement of the first blade and the second blade is to cause eddies in the air surrounding the first and the second blades.

2. The winged piezo-fan of claim 1, wherein the first blade and the second blade move in the upward direction in response to compression in the physical dimension of the piezo-ceramic element.

3. The winged piezo-fan of claim 1, wherein the first blade and the second blade move in the downward direction in response to elongation in the physical dimension of the piezo-ceramic element.

4. The winged piezo-fan of claim 2, wherein the upward direction of the first blade and the second blade is along a plane perpendicular to an axis of the first blade and the second blade, wherein the axis is drawn along the length of the first blade and the second blade.

5. The winged piezo-fan of claim 3, wherein the downward direction of the first blade and the second blade is along a plane perpendicular to an axis of the first blade and the second blade, wherein the axis is drawn along the length of the first blade and the second blade.

6. The winged piezo-fan of claim 1, wherein the first blade and the second blade is hinged to the piezo-ceramic element at one end.

7. A system comprising:
a daughter card is to comprise a first set of memory chips on a first plane and a second set of memory chips on a second plane of the daughter card, and
a winged piezo-fan is to comprise a first blade and a second blade coupled to a piezo-ceramic element,
wherein a flapping movement of the first blade and the second blade is caused by the change in the physical dimension of the piezo-ceramic element in response to receiving an alternating voltage signal,
wherein the flapping movement is to create turbulence in the surrounding air and the turbulence is to create circular movement of the surrounding air that dissipates the heat generated by the first set of memory chips and the second set of memory chips.

8. The system of claim 7, wherein the first blade and the second blade move in an upward direction in response to compression in the physical dimension of the piezo-ceramic element.

9. The system of claim 7, wherein the first blade and the second blade move in the downward direction in response to elongation in the physical dimension of the piezo-ceramic element.

10. The system of claim 8, wherein the upward direction of the first blade and the second blade is along a plane perpendicular to an axis of the first blade and the second blade, wherein the axis is drawn along the length of the first blade and the second blade.

11. The system of claim 9, wherein the downward direction of the first blade and the second blade is along a plane perpendicular to an axis of the first blade and the second blade, wherein the axis is drawn along the length of the first blade and the second blade.

12. The system of claim 7, wherein the first blade and the second blade is hinged to the piezo-ceramic element at one end.

13. The system of claim 8, wherein the movement of the first blade and the second blade in the upward direction generates circular movement of the surrounding air that dissipates the heat generated by the first set of memory chips of the daughter card.

14. The system of claim 9, wherein the movement of the first blade and the second blade in the downward direction generates circular movement of the surrounding air that dissipates the heat generated by the second set of memory chips of the daughter card.
